(19) United States
(12) Patent Application Publication
(10) Pub. No.: US 2025/0383945 A1
(43) Pub. Date: Dec. 18, 2025

(54) RADIATION SENSOR SUITE

(71) Applicant: Micron Technology, Inc., Boise, ID (US)

(72) Inventors: Preeti Kumari, Boise, ID (US); Chiara Cerafogli, Boise, ID (US); Maithilee Motlag, Boise, ID (US); Silvia Beltrami, Almenno San Bartolomeo (IT); Kiran Rode, Boise, ID (US)

(21) Appl. No.: 19/232,241

(22) Filed: Jun. 9, 2025

Related U.S. Application Data
(60) Provisional application No. 63/659,422, filed on Jun. 13, 2024.

(51) Int. Cl. G06F 11/07; G06F 3/06; H10B 41/41; H10B 43/40; H10B 80/00

(52) U.S. Cl. CPC G06F 11/0706; G06F 3/0679; G06F 11/0793; H10B 41/41; H10B 43/40; H10B 80/00

(57) ABSTRACT

The present disclosure includes apparatuses, methods, and systems for a radiation sensor suite. In an example, a method can include calibrating a plurality of sensors of a sensor suite located on a non-volatile memory die and monitoring for a plurality of radiation events at each one of the plurality of sensors. In response to none of the plurality of sensors detecting a radiation event, the method can include the sensor suite continuing to monitor for the plurality of radiation events. In response to at least one of the plurality of radiation sensors detecting a radiation event, the method can include notifying a host of the radiation event and identifying a NAND flash memory array region affected and correcting the radiation event based on the radiation event and the NAND flash memory array region affected.

### PRIORITY INFORMATION

This application claims the benefit of U.S. Provisional Application No. 63/659,422, filed on Jun. 13, 2024, the contents of which are incorporated herein by reference.

### TECHNICAL FIELD

The present disclosure relates generally to non-volatile memory and methods, and more particularly, to a radiation sensor suite detecting radiation events on a memory cell die.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), static random access memory (SRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random-access memory (RRAM), and magnetic random-access memory (MRAM), among others.

A host can utilize memory devices to store data. A host can be a computer or other device that communicates with other hosts on a network. A host controller can act as a bridge to allow connection between a host and external or internal computer peripherals.

### BRIEF DESCRIPTION OF THE DRAWINGS

FIG. 1 is a block diagram of a computing system including a host and an apparatus in the form of a memory device in accordance with an embodiment of the present disclosure.

FIG. 2 is a block diagram of a memory device including a number of non-volatile memory dies in accordance with an embodiment of the present disclosure.

FIG. 3 is a block diagram of a memory die including a radiation sensor suite in accordance with an embodiment of the present disclosure.

FIG. 4 is a block diagram of a radiation sensor suite in accordance with an embodiment of the present disclosure.

FIG. 5 is a flow diagram of a method for detecting a radiation event in accordance with an embodiment of the present disclosure.

### DETAILED DESCRIPTION

The present disclosure includes apparatuses, methods, and systems for detecting radiation events at a memory die. In an example, a method can include calibrating a plurality of sensors of a sensor suite located on a non-volatile memory die and monitoring for a plurality of radiation events at each one of the plurality of sensors. In response to none of the plurality of sensors detecting a radiation event, the sensor suite can continue to monitor for the plurality of radiation events. In response to at least one of the plurality of radiation sensors detecting a radiation event, a host can be notified of the radiation event and a NAND flash memory array region affected can be identified. The method can further include correcting the radiation event based on the radiation event and the NAND flash memory array region affected.

A sensor suite can include a plurality of sensors. The sensors can be a same type or different types. The sensors, for example, can include solid-state radiation sensors including, but not limited to doped solid-state diodes (e.g., PN junctions) that produce voltage/current transient signals (e.g., pulse) in response to ionizing radiation. The dopant level and type can determine its sensitivity and what type it's tuned to detect. The shape and arrangement of the diodes can determine the direction and angle of radiation it's tuned to detect. A sensor, in some examples, may include a portion of a memory cell (e.g., capacitor of a DRAM cell, NAND cell, sense-amp latch circuit, or SRAM) that is located closer to the surface for radiation exposure/sensitivity and the signal being monitored may be a characteristic of that portion (e.g., capacitance discharge voltage, NAND cell threshold voltage, or SRAM bit error, etc.).

Volatile and non-volatile memory can be affected by radiation exposure (e.g., a radiation event). For example, a radiation event can be a limiting factor to memory performance and output and can affect functionality of products utilizing the memory. For instance, NAND memory array radiation exposure impacts can include memory cell voltage shifts, page buffer changes, SRAM changes, DRAM changes, etc. These changes can negatively affect a desired memory function and/or memory performance. For example, overlapping cell voltages within a NAND flash memory array caused by a radiation shift may result in read errors.

Correction of radiation events may include rebooting a system (e.g., power down/power up), which can be time consuming. Examples of the present disclosure can utilize a sensor suite on a memory die to detect a radiation event, and a correction can be triggered to a particular affected area, rather than a complete reboot. For instance, a particular register may be reset to address a specific radiation event as opposed to rebooting and causing downtime to an entire device and/or system.

As used herein, “a”, “an”, or “a number of” can refer to one or more of something, and “a plurality of” can refer to two or more such things. For example, a memory device can refer to one or more memory devices, and a plurality of memory devices can refer to two or more memory devices. Additionally, the designators “X” and “Y”, as used herein, particularly with respect to reference numerals in the drawings, indicates that a number of the particular feature so designated can be included with a number of embodiments of the present disclosure. The number may be the same or different between designations.

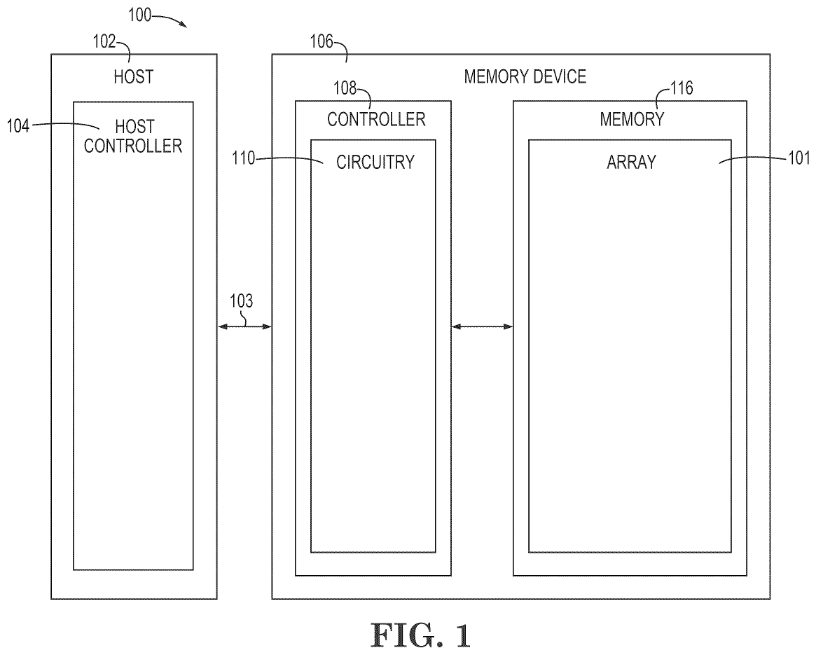

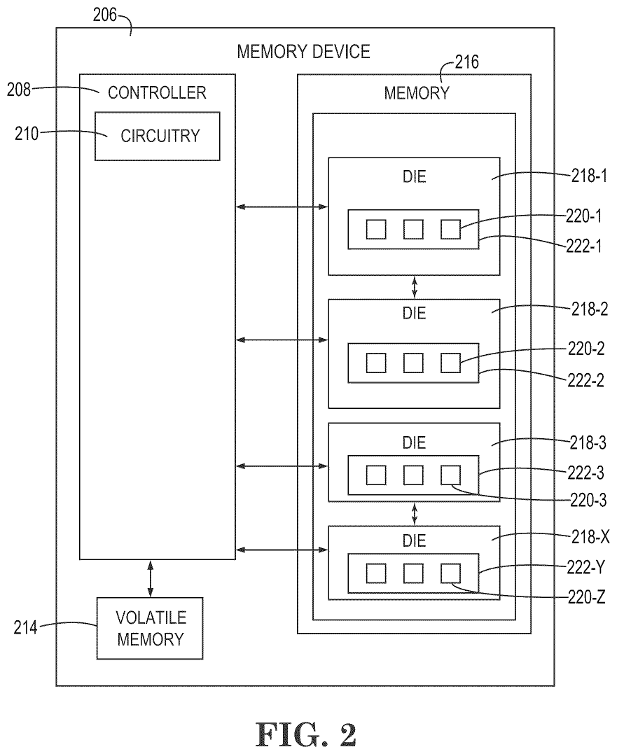

The figures herein follow a numbering convention in which the first digit or digits correspond to the drawing figure number and the remaining digits identify an element or component in the drawing. Similar elements or components between different figures may be identified by the use of similar digits. For example, 106 may reference element “06” in FIG. 1, and a similar element may be referenced as 206 in FIG. 2.

FIG. 1 is a block diagram of a computing system 100 including a host 102 and an apparatus in the form of a memory device 106 in accordance with an embodiment of the present disclosure. As used herein, an “apparatus” can refer to, but is not limited to, any of a variety of structures or combinations of structures, such as a circuit or circuitry, a die or dice, a module or modules, a device or devices, or a system or systems, for example. Further, in an embodiment, computing system 100 can include a number of memory devices analogous to memory device 106.

In the embodiment illustrated in FIG. 1, memory device 106 can include a memory 116 having a memory array 101. Memory 116 can be one or more memory dies. Although one memory array 101 is illustrated in FIG. 1, memory 116 can include any number of memory arrays analogous to memory array 101.

Memory array 101 can be, for example, a flash memory array such as a NAND flash memory array. As an additional example, memory array 101 can be a resistance variable memory array such as a PCRAM, RRAM, MMRAM, or spin torque transfer (STT) array, among others. However, embodiments of the present disclosure are not limited to a particular type of memory array. Further, although not shown in FIG. 1, memory array 101 can be located on a particular semiconductor die along with various peripheral circuitry associated with the operation thereof.

Memory array 101 can have a number of physical blocks of memory cells. The memory cells can be single level cells and/or multilevel cells such as, for instance, two level cells, triple level cells (TLCs) or quadruple level cells (QLCs). As an example, the number of physical blocks in memory array 101 may be 128 blocks, 512 blocks, or 1,024 blocks, but embodiments are not limited to a particular power of two or to any particular number of physical blocks in memory array 101.

A number of physical blocks of memory cells can be included in a plane of memory cells, and a number of planes of memory cells can be included on a die. For instance, each physical block can be part of a single die. That is, the portion of memory array 101 illustrated in FIG. 1 can be a die of memory cells. Each physical block can include a number of physical rows of memory cells coupled to access lines (e.g., word lines). The number of rows (e.g., word lines) in each physical block can be 32, but embodiments are not limited to a particular number of rows per physical block. Further, although not shown in FIG. 1, the memory cells can be coupled to columns of sense lines (e.g., data lines and/or digit lines).

As one of ordinary skill in the art will appreciate, each row can include a number of pages of memory cells (e.g., physical pages). A physical page refers to a unit of programming and/or sensing (e.g., a number of memory cells that are programmed and/or sensed together as a functional group). In a number of embodiments, each row can comprise one physical page of memory cells. However, embodiments of the present disclosure are not so limited. For instance, in an embodiment, each row can comprise multiple physical pages of memory cells (e.g., one or more even pages of memory cells coupled to even-numbered data lines, and one or more odd pages of memory cells coupled to odd numbered data lines). Additionally, for embodiments including multilevel cells, a physical page of memory cells can store multiple pages (e.g., logical pages) of data (e.g., an upper page of data and a lower page of data, with each cell in a physical page storing one or more bits towards an upper page of data and one or more bits towards a lower page of data).

In some examples, a page of memory cells can comprise a number of physical sectors (e.g., subsets of memory cells). Each physical sector of cells can store a number of logical sectors of data. Additionally, each logical sector of data can correspond to a portion of a particular page of data. As an example, a first logical sector of data stored in a particular physical sector can correspond to a logical sector corresponding to a first page of data, and a second logical sector of data stored in the particular physical sector can correspond to a second page of data. Each physical sector can store system and/or user data, and/or can include overhead data, such as error correction code (ECC) data, logical block address (LBA) data, and metadata.

Logical block addressing is a scheme that can be used by a host for identifying a logical sector of data. For example, each logical sector can correspond to a unique logical block address (LBA). Additionally, an LBA may also correspond (e.g., dynamically map) to a physical address, such as a physical block address (PBA), that may indicate the physical location of that logical sector of data in the memory. A logical sector of data can be a number of bytes of data (e.g., 256 bytes, 512 bytes, 1,024 bytes, or 4,096 bytes). However, embodiments are not limited to these examples.

It is noted that other configurations for the physical blocks, rows, sectors, and pages are possible. For example, rows of physical blocks can each store data corresponding to a single logical sector which can include, for example, more or less than 512 bytes of data.

As illustrated in FIG. 1, host 102 can be coupled to the memory device 106 via host interface 103. Host 102 and memory device 106 can communicate (e.g., send commands and/or data) on host interface 103. The computing system 100 including host 102 and/or memory device 106 can be, or be part of, an Internet of Things (IoT) enabled device, a vehicle, an automation tool, an industrial protocol camera among other host systems, and can include a memory access device (e.g., a processor). One of ordinary skill in the art will appreciate that “a processor” can intend one or more processors, such as a parallel processing system, a number of coprocessors, etc.

Host interface 103 can be in the form of a standardized physical interface. For example, when memory device 106 is used for information storage in computing system 100, host interface 103 can be a serial advanced technology attachment (SATA) physical interface, a peripheral component interconnect express (PCIe) physical interface, a universal serial bus (USB) physical interface, or a small computer system interface (SCSI), among other physical connectors and/or interfaces. In general, however, host interface 103 can provide an interface for passing control, address, information (e.g., data), and other signals between memory device 106 and host 102 having compatible receptors for host interface 103.

Memory device 106 includes controller 108 to communicate with host 102 and with memory 116 (e.g., memory array 101). For instance, controller 108 can send commands to perform operations on memory array 101, including operations to sense (e.g., read), program (e.g., write), move, and/or erase data, among other operations.

Controller 108 can be included on the same physical device (e.g., the same die) as memory 116. Alternatively, controller 108 can be included on a separate physical device that is communicatively coupled to the physical device that includes memory 116. In an embodiment, components of controller 108 can be spread across multiple physical devices (e.g., some components on the same die as the memory, and some components on a different die, module, or board) as a distributed controller.

The host 102 can include a host controller 104 to communicate with memory device 106. The host controller 104 can be coupled to and/or send commands to memory device 106 and/or controller 108 via host interface 103. The host controller 104 can communicate with memory device 106 and/or the controller 108 on the memory device 106 to read, write, and/or erase data, among other operations. For example, the host 102 can transmit a power on command to the memory device 106 to initialize (e.g., boot, turn on, start, etc.) the memory device 106 and/or transmit a trace failure command to receive a non-volatile memory die initialization failure. In a number of embodiments, the host 102 can further receive an alarm that the memory device 106 is unstable due to a non-volatile memory die initialization failure (e.g., an error occurring during the initialization of the non-volatile memory die).

Controller 108 on memory device 106 and/or the host controller 104 on host 102 can include control circuitry and/or logic (e.g., hardware and firmware). In an embodiment, controller 108 on memory device 106 and/or the host controller 104 on host 102 can be an application specific integrated circuit (ASIC) coupled to a printed circuit board including a physical interface. Also, memory device 106 and/or host 102 can include a buffer of volatile and/or non-volatile memory and one or more registers.

For example, as shown in FIG. 1, memory device 106 can include circuitry 110. In the embodiment illustrated in FIG. 1, circuitry 110 is included in controller 108. However, embodiments of the present disclosure are not so limited. For instance, in an embodiment, circuitry 110 may be included in (e.g., on the same die as) memory 116 (e.g., instead of in controller 108). Circuitry 110 can comprise, for instance, hardware, firmware, and/or software for performing operations described herein. For example, the circuitry 110 can be configured to initialize the controller 108 and a volatile memory die prior to initializing a non-volatile memory die.

FIG. 2 is a block diagram of a memory device 206 including a number of non-volatile memory dies 218-1, 218-2, 218-3, and 218-X in accordance with an embodiment of the present disclosure. The memory device 206 can correspond to memory device 106 in FIG. 1. A controller 208 and a memory 216 corresponding to controller 108 and memory 116 in FIG. 1, respectively can be included in the memory device 206. The controller 208 can include circuitry 210 corresponding to circuitry 110 in FIG. 1. In some examples, the controller 208 can be coupled to a volatile memory die 214, which can include an SRAM array, for example.

The memory 216 can be non-volatile memory including the number of non-volatile memory dies 218-1, . . . , 218-X. In a number of embodiments, the non-volatile memory dies 218-1, . . . , 218-X can be NAND flash memory array dies. Non-volatile memory dies 218-1, . . . , 218-X can include radiation sensor suites 222-1 . . . , 222-Y, each having a plurality of sensors 220-1, . . . , 220-Z. While only one sensor is labeled in FIG. 2 on each of the plurality of sensor suites 222, and only three sensors are shown, more or fewer sensors 220 may be present on each sensor suite 222.

The sensors 220 of the sensor suites 222 can be calibrated to detect and/or recognize particular radiation events and strengths. The sensor suites 222 can monitor an associated non-volatile memory die 218-1, . . . , 218-X of the plurality of memory dies 218. The monitoring, for instance can be continuous (with little or no down-time), periodically (e.g., at certain time intervals), or on-demand (e.g., monitoring can be turned “off” or “on”). An event can be received at one of the plurality of sensor suites 222, and a determination can be made whether the event is a radiation event. For example, the sensors 220 of the sensor suites 222 can have a “weak” radiation layout, meaning the sensors 220 are meant to be more sensitive to radiation events as compared to other sensors. The more sensitive sensors 220 can detect radiation quickly as compared to less sensitive sensors, resulting in a faster alert time and correction time.

The radiation event may include, for instance, an x-ray, a gamma ray, a cosmic ray, radio waves, microwaves, infrared, visible light, ultraviolet, etc., and each of the plurality of sensors 220 can be sensitive to a particular type of radiation and/or to a particular type of elements susceptible to radiation. In some examples, the radiation event may non-visible light radiation such as heavy ion bombardment and/or ionizing radiation, among others.

In response to determining the event is not a radiation event, the sensor suites 222 can continue to monitor the associated non-volatile memory dies 218. In response to determining the event is a radiation event, the radiation event can be correlated to a particular type of circuitry, memory cell, or both in an associated high voltage memory, and a controller 208 can be notified of the radiation event, as well as the particular type of circuitry, memory cell, or both affected. Examples can include NAND flash memory cells, cell voltage, page buffer, SRAM memory cells, circuitry errors, etc. Examples of a particular type of circuitry, memory cell, or both, are not so limited, however.

The controller 208 can be coupled to the plurality of non-volatile memory dies 218 and can trigger a correction of the radiation event based on the radiation event and the particular type of circuitry and memory cell affected. The correction, for example, can include the controller 208 sending a corrective measure to a host device (e.g., host 102 and/or host controller 104 illustrated in FIG. 1). The corrective measure may include, for instance, shifting a voltage distribution to a correct state (e.g., pre-radiation event).

Example corrective measures can take less time, less energy, or both as compared to failure of an apparatus, such as the memory device. For example, a register may be reset instead of a total power down/power up process. A register reset, a voltage distribution shift, etc. can take less time and/or energy as opposed to other corrective measures. In addition, the corrective measure can target the location affected by the radiation, while other portions of the memory device 206 can remain unaffected.

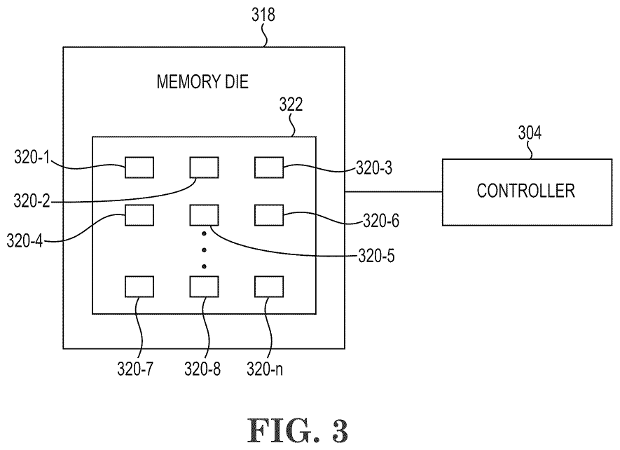

FIG. 3 is a block diagram of a memory die 318 including a radiation sensor suite 322 in accordance with an embodiment of the present disclosure. The memory die 318 can be a non-volatile memory die, and the radiation sensor suite 322 can be housed on the memory die 318 and can include a plurality of sensors 320-1, . . . , 320-n. The plurality of sensors 320 can receive, or be exposed to, a radiation event. The plurality of sensors 320 can sense the radiation event and determine a category of the radiation event. For example, each one of the plurality of sensors 320 can be a different sensor type, and/or each one of the plurality of sensors 320 can be sensitive to a different particular radiation event type. For instance, sensor 320-1 may be sensitive to gamma rays, while sensor 320-3 may be sensitive to x-rays. Each one of the plurality of sensors 320 can be calibrated to a particular radiation event sensitivity. For example, sensor 320-4 may be calibrated to a particular radiation event sensitivity (e.g., sensitivity threshold) for cosmic rays, while sensor 320-2 may be calibrated to a particular radiation event sensitivity for radio waves.

In some examples, determining a category can include measuring currents and/or signals from two or more sensors and comparing it to one or more stored profiles or look-up tables. Categorization, in some examples, can include monitoring for particular behavior, for instance, a transient voltage with a sharp pulse may indicate a single heavy ion bombardment, whereas transient current may indicate sustained alpha/beta/gamma exposure.

More than one radiation event may be detected by the sensor suite 322. For instance, a first one (e.g., sensor 320-1) of the plurality of sensors 320 can sense the radiation event, and a second one (e.g., sensor 320-2) of the plurality of sensors 320 can sense a different radiation event simultaneously. The radiation event(s) can be correlated to particular circuitry associated with the memory die 318, and a controller 304 coupled to the memory die can be notified of the radiation event, the correlation, and the radiation event category. For example, if one of the plurality of sensors 320 detects radiation that is likely to affect a SRAM, the radiation event is correlated to SRAM, so appropriate corrections can be made.

The controller 304 can receive the indication of the radiation event from at least one sensor (e.g., sensor 320-2) of the plurality of sensors 320 and can trigger a correction to the radiation event based on the radiation event, the correlation, and the radiation event category. For instance, the radiation event may affect a particular memory cell type and based on the radiation event and affected memory cell type, an appropriate correction can be triggered or made, for instance, a register reset. The controller 304 can be located on a same NAND memory device as the memory die 318 or may be a host controller coupled to a NAND memory device housing the non-volatile memory die 318.

In some examples, the determining correlating, and notifying regarding the radiation event may be performed by a controller, such as the controller 304 or a local controller not illustrated herein. For instance, the sensor suite 322 can provide signals to the controller, which performs the determination, correlation, and notification, among others.

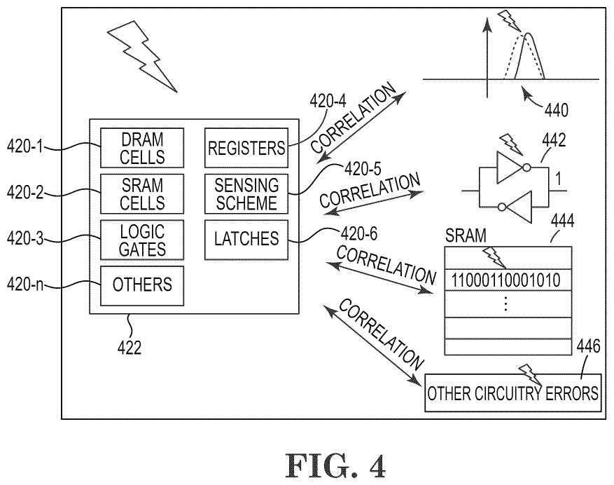

FIG. 4 is a block diagram of a radiation sensor suite 422 in accordance with an embodiment of the present disclosure. The sensor suite 422 can include a plurality of sensors 420-1, . . . , 420-n that can detect radiation events received at the sensor suite 422. The sensor suite 422 can be, for instance located on a memory die of a non-volatile memory device. While the plurality of sensors 420 are illustrated in a particular layout in FIG. 4, other sensor layouts on the sensor suite 422 are possible.

The sensor suite 422 can be sensitive to a plurality of different radiation events, and each one of the plurality of sensors 420 can be sensitive to a particular radiation event and/or target. For instance, sensor 420-1 may be sensitive to radiation that affects DRAM memory cells, sensor 420-2 may be sensitive to radiation that affects SRAM memory cells, and sensor 420-3 may be sensitive to radiation that affects logic gates. Similarly, sensor 420-4 may be sensitive to radiation that affects registers, sensor 420-5 may be sensitive to radiation that affects a sensing scheme, and sensor 420-6 may be sensitive to radiation affecting latches. Other sensor types may be present on a sensor suite 422, as illustrated at sensor 420-n.

A radiation event can be detected that the sensor suite 422, and based on the event detected, a region and/or circuitry sensitive to that type of radiation event can be determined. For instance, at 440, a correlation can be determined between the radiation event and a cell impact for a read window budget (RWB) algorithm re-try or correction. For example, radiation may cause a voltage distribution shift, such that the entire distribution may shift as shown in FIG. 4 from the solid voltage distribution curve of correlation 440 to the dotted voltage distribution curve of correlation 440. This can indicate a change of state in a memory array, for example, and can result in inaccurate, incomplete, incorrect, and/or undesired performance, outputs, and functionality.

At 442, a correlation can be determined between the radiation event and a page buffer or other sensing scheme. For instance, correlation 442 illustrates the radiation causing a change in state, for instance a shift from a 0 to a 1, and this change can result in inaccurate, incorrect, incomplete, and/or undesired performance and functionality. At 444, the radiation event may be correlated to an SRAM device, which may also cause a change in state and resulting inaccurate, incorrect, incomplete, and/or undesired performance, outputs, and functionality. A correlation may be made to other regions and/or circuitry errors, as illustrated at box 446. More than one radiation event can be detected at a time at the sensor suite 422, and accordingly, more than one correlation can be made. The radiation events may correlate to same or different regions and/or circuitry, in some examples.

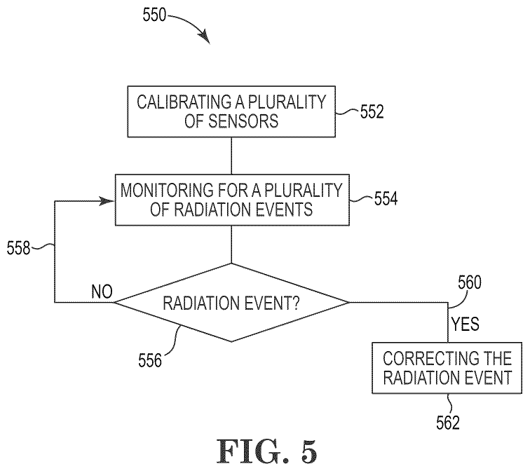

FIG. 5 is a flow diagram of a method 550 for detecting a radiation event in accordance with an embodiment of the present disclosure. At block 552, the method 550 can include calibrating a plurality of sensors of a sensor suite located on a non-volatile memory die. Calibration can include determining how sensitive each sensor of the sensor suite should be in order to detect radiation early enough to correct its effects on the memory cell and/or system. Calibration can include testing different sensitivities of the sensors and different amounts of different radiation types to determine which sensors and sensor settings are appropriate. This can include testing different amounts and types of radiation to determine how the sensors and/or associate circuitry may be affected. The calibration can be performed on high volume manufacturing data to increase accuracy of the sensitivity and radiation correlation. This calibration can be adjusted or reperformed in response to actual radiation events and corrections occurring.

At block 554, the method 550 can include monitoring for a plurality of radiation events at each one of the plurality of sensors. The monitoring can be continuous, periodic, performed in response to a monitor command or set feature, or a combination thereof. Each of the plurality of sensors can be sensitive to a particular threshold of radiation from a particular radiation type.

At block 556, the method 550 can include determining whether a radiation event has been detected. In response to none of the plurality of sensors detecting a radiation event, at 558, the sensor suite can continue to monitor for the plurality of radiation events. In response to at least one of the plurality of radiation sensors detecting a radiation event, at 560, a host can be notified of the radiation event and a NAND flash memory array region affected. A system comprising the host and the non-volatile memory die may be notified of the radiation event instead of, or in addition to, the host.

At block 562, the method 550 can include correcting the radiation event based on the radiation event and the NAND flash memory array region affected. For example, in response to a first one of the plurality of radiation sensors detecting a first radiation event and a second one of the plurality of radiation sensors detecting a second, different radiation event, the host can be notified of the first and the second radiation events and the respective first and second NAND flash memory array regions affected can be identified. The first and the second radiation events can be corrected based on the respective first and second radiation events and the respective first and second NAND flash memory array regions affected.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A system, comprising:
a non-volatile memory die;
a sensor suite housed on the non-volatile memory die and comprising a plurality of sensors configured to:
sense a radiation event;
determine a category of the radiation event;
correlate the radiation event to particular circuitry associated with the non-volatile memory die; and
notify a controller of the radiation event, the correlation, and the radiation event category;
the controller coupled to the non-volatile memory die, the controller including circuitry configured to:
receive indication of the radiation event from at least one sensor of the plurality of sensors; and
trigger a correction to the radiation event based on the radiation event, the correlation, and the radiation event category.

2. The system of claim 1, wherein at least two of the plurality of sensors are different sensor types.

3. The system of claim 1, wherein each one of the plurality of sensors is sensitive to a different particular radiation event type.

4. The system of claim 1, wherein each one of the plurality of sensors is calibrated to a particular radiation event sensitivity.

5. The system of claim 1, wherein the controller is located on a same NAND memory device as the non-volatile memory die.

6. The system of claim 1, wherein the controller is a host controller coupled to a NAND memory device housing the non-volatile memory die.

7. The system of claim 1, wherein:
a first one of the plurality of sensors senses the radiation event; and
a second one of the plurality of sensors senses a different radiation event simultaneously.

8. An apparatus, comprising:
a plurality of non-volatile memory dies;
a plurality of sensor suites, wherein each one of the plurality of non-volatile memory dies houses one of the plurality of sensor suites, each one of the plurality of sensor suites comprising a plurality of radiation-sensitive sensors, the plurality of sensor suites configured to:
continuously monitor an associated non-volatile memory die of the plurality of memory dies;
receive an event at the one of the plurality of sensor suites;
determine whether the event is a radiation event;
in response to determining the event is not a radiation event, continue to monitor the associated non-volatile memory die;
in response to determining the event is a radiation event, correlate the radiation event to a particular type of circuitry, memory cell, or both in an associated high voltage memory; and
notify a controller of the radiation event, and the particular type of circuitry, memory cell, or both affected; and
the controller coupled to the plurality of non-volatile memory dies and configured to trigger a correction of the radiation event based on the radiation event and the particular type of circuitry, memory cell, or both affected.

9. The apparatus of claim 8, where the radiation event comprises at least one of an x-ray, a gamma ray, or a cosmic ray.

10. The apparatus of claim 8, wherein the controller configured to trigger the correction comprises the controller configured to send a corrective measure to a host.

11. The apparatus of claim 10, wherein the corrective measure comprises a measure that takes less time, less energy, or both as compared to failure of the apparatus.

12. The apparatus of claim 8, wherein the memory cell comprises NAND flash memory.

13. The apparatus of claim 8, wherein the particular type of circuitry, memory cell, or both comprises at least one of a cell voltage, a page buffer, static random-access memory (SRAM), dynamic random-access memory (DRAM), and a circuitry error.

14. A method, comprising:
calibrating a plurality of sensors of a sensor suite located on a non-volatile memory die;
monitoring for a plurality of radiation events at each one of the plurality of sensors;
in response to none of the plurality of sensors detecting a radiation event, the sensor suite continuing to monitor for the plurality of radiation events;
in response to at least one of the plurality of radiation sensors detecting a radiation event, notifying a host of the radiation event and identifying a NAND flash memory array region affected; and
correcting the radiation event based on the radiation event and the NAND flash memory array region affected.

15. The method of claim 14, wherein monitoring for the plurality of radiation events comprises continuously monitoring for the plurality of radiation events.

16. The method of claim 14, wherein monitoring for the plurality of radiation events comprises periodically monitoring for the plurality of radiation events.

17. The method of claim 14, wherein monitoring for the plurality of radiation events comprises monitoring for the plurality of radiation events responsive to a monitor command or set feature.

18. The method of claim 14, wherein in response to a first one of the plurality of radiation sensors detecting a first radiation event and a second one of the plurality of radiation sensors detecting a second, different radiation event, notifying the host of the first and the second radiation events and identifying respective first and second NAND flash memory array regions affected.

19. The method of claim 18, comprising correcting the first and the second radiation events based on the respective first and second radiation events and the respective first and second NAND flash memory array regions affected.

20. The method of claim 14, wherein in response to at least one of the plurality of radiation sensors detecting the radiation event, notifying a system comprising the host and the non-volatile memory die of the radiation event and identifying a NAND flash memory array region of the system affected.
